(19) United States
(12) Patent Application Publication
(10) Pub. No.: US 2021/0356995 A1
(43) Pub. Date: Nov. 18, 2021

(54) DISPLAY PANEL AND DISPLAY DEVICE

(71) Applicant: Wuhan China Star Optoelectronics Semiconductor Display Technology Co., Ltd., Wuhan (CN)

(72) Inventor: Xia CHEN, Wuhan (CN)

(73) Assignee: Wuhan China Star Optoelectronics Semiconductor Display Technology Co., Ltd., Wuhan (CN)

(21) Appl. No.: 16/613,132

(22) PCT Filed: Oct. 15, 2019
(86) PCT No.: PCT/CN2019/111206

§ 371 Date: Nov. 13, 2019

(30) Foreign Application Priority Data
May 30, 2019 (CN) 201910465080.0

(51) Int. Cl. G06F 1/16; G06F 3/041; G02B 5/30

(52) U.S. Cl. CPC G06F 1/1656; G02B 5/3033; G06F 3/0412; G06F 1/1652

(57) ABSTRACT

The present invention discloses a display panel and a display device, the display panel includes a display region and a non-display region located outside the display region. The display panel includes a first buffer layer and a plurality of display region film layers. The first buffer layer is located in the non-display region. The first buffer layer flexibly connects to at least two of the plurality of display region film layers. The present invention can resist the shear stress between the display region film layers, and prevent the display panel from peeling.

### FIELD OF INVENTION

The present invention is related to the field of display technology, and specifically to a display panel and a display device.

### BACKGROUND OF INVENTION

With rapid development of electronic products, flexible organic light-emitting diodes (OLEDs) having a fixed curved surface has gradually become mainstream of the field of display technology due to their excellent performances, such as low power consumption, high color saturation, and wide viewing angles.

Accordingly, major mobile phone electronics manufacturers are racing to develop flexible and bendable products. Flexible and bendable products require their modules and materials to be all bendable. Most display panels adopt a laminated structure. In the bending process, the laminated structure has a shearing effect between layers, and displacement occurs between the layers of a display region. If it is not reset in time, a boundary it will happen a lack of glue, and forming a potential risk for peeling. After bending many times, it may cause the peeling inward from the boundary. In the process of high temperature bending, this phenomenon is more obvious.

To summarize, in the prior art, displacement occurs between layers of a display region of a display panel during the bending process, and it may cause peeling of the layers of the display panel.

### SUMMARY OF INVENTION

In the prior art, displacement occurs between layers of a display region of a display panel during the bending process, and it may cause peeling of the layers of the display panel.

The present invention provides a display panel and a display device that can buffer the displacement between the layers of the display region of the display panel during the bending process, and prevent the layers of the display panel from peeling.

To solve the peeling problem, first, the present invention provides a display panel, and the display panel includes a display region and a non-display region located outside the display region.

The display panel includes a first buffer layer and a plurality of display region film layers. The first buffer layer is located in the non-display region. The first buffer layer flexibly connects to at least two of the plurality of display region film layers.

The plurality of display region film layers include a display layer, a polarizer, and a touch layer disposed in sequence. A backplate layer is disposed on a side of the display layer away from the polarizer. A cover plate layer is disposed on the side of the touch layer away from the polarizer. The first buffer layer flexibly connects to the backplate layer, the display layer, the polarizer, the touch layer, the cover plate layer.

The first buffer layer is selected from the group consisting of photoresist, rubber, an acrylate, polyurethane, and silicone.

The cover plate layer and the backplate layer are located in the display region. One side surface of the first buffer layer is coplanar with a side surface of the cover plate layer away from the touch layer. The other side surface of the first buffer layer is coplanar with a side surface of the backplate layer away from the display layer. The one side surface of the first buffer layer attaches to the backplate layer, the display layer, the polarizer, the touch layer, and the side surface of the cover plate layer. The one side surface of the first buffer layer flexibly connects to the backplate layer, the display layer, the polarizer, the touch layer, and the cover plate layer.

To solve the peeling problem, second, the present invention provides a display panel, and the display panel includes a display region, a non-display region located outside the display region.

The display panel includes a first buffer layer and a plurality of display region film layers. The first buffer layer is located in the non-display region, and the first buffer layer flexibly connects to at least two of the plurality of display region film layers.

The plurality of display region film layers include a display layer, a polarizer, and a touch layer disposed in sequence. A backplate layer is disposed on a side of the display layer away from the polarizer. A cover plate layer is disposed on the side of the touch layer away from the polarizer. The first buffer layer flexibly connects to the backplate layer, the display layer, the polarizer, the touch layer, the cover plate layer.

The cover plate layer and the backplate layer are located in the display region. One side surface of the first buffer layer is coplanar with a side surface of the cover plate layer away from the touch layer. The other side surface of the first buffer layer is coplanar with a side surface of the backplate layer away from the display layer. The one side surface of the first buffer layer attaches to the backplate layer, the display layer, the polarizer, the touch layer, and the side surface of the cover plate layer. The one side surface of the first buffer layer flexibly connects to the backplate layer, the display layer, the polarizer, the touch layer, and the cover plate layer.

The display panel further includes a second buffer layer located in the display region. The cover plate layer and the backplate layer are located in the display region. The second buffer layer is integrally formed with the first buffer layer. The second buffer layer attaches to the side surface of the cover plate layer away from the touch layer and the side surface of the backplate layer away from the display layer. The one side surface of the first buffer layer attaches to the backplate layer, the display layer, the polarizer, the touch layer, and the cover plate layer. The one side surface of the first buffer layer flexibly connects to the backplate layer, the display layer, the polarizer, the touch layer, and the cover plate layer.

The cover plate layer and the backplate layer cover the display region and extend to the non-display region. The one side surface of the first buffer layer attaches to a side surface of the cover plate layer near the touch layer. The other side surface of the first buffer layer attaches to a side surface of the backplate layer near the display layer. The one side surface of the first buffer layer attaches to the display layer, the polarizer, and the touch layer. The one side surface of the first buffer layer flexibly connects to the backplate layer, the display layer, the polarizer, the touch layer, and the cover plate layer.

The cover plate layer covers the display region and extend to the non-display region. The backplate layer is located in the display region. The one side surface of the first buffer layer attaches to the side surface of the cover plate layer near the touch layer. The other side surface of the first buffer layer is coplanar with the side surface of the backplate layer away from the display layer. The one side surface of the first buffer layer attaches to the backplate layer, the display layer, the polarizer, and a side surface of the touch layer. The one side surface of the first buffer layer flexibly connects to the backplate layer, the display layer, the polarizer, the touch layer, and the cover plate layer.

The first buffer layer is selected from the group consisting of photoresist, rubber, an acrylate, polyurethane, and silicone.

Any neighboring two surfaces of film layers of the backplate layer, the display layer, the polarizer, the touch layer, and the cover plate layer are connected by a binding material.

The binding material is photoresist.

To solve the peeling problem, third, the present invention provides a display device, and the display device includes a display panel. The display panel includes a display region, a non-display region located outside the display region.

The display panel includes a first buffer layer and a plurality of display region film layers. The first buffer layer is located in the non-display region. The first buffer layer flexibly connects to at least two of the plurality of display region film layers.

The plurality of display region film layers include a display layer, a polarizer, and a touch layer disposed in sequence. A backplate layer is disposed on a side of the display layer away from the polarizer. A cover plate layer is disposed on the side of the touch layer away from the polarizer. The first buffer layer flexibly connects to the backplate layer, the display layer, the polarizer, the touch layer, the cover plate layer.

The cover plate layer and the backplate layer are located in the display region. One side surface of the first buffer layer is coplanar with a side surface of the cover plate layer away from the touch layer. The other side surface of the first buffer layer is coplanar with a side surface of the backplate layer away from the display layer. The one side surface of the first buffer layer attaches to the backplate layer, the display layer, the polarizer, the touch layer, and the side surface of the cover plate layer. The one side surface of the first buffer layer flexibly connects to the backplate layer, the display layer, the polarizer, the touch layer, and the cover plate layer.

The display panel further includes a second buffer layer located in the display region. The cover plate layer and the backplate layer are located in the display region. The second buffer layer is integrally formed with the first buffer layer. The second buffer layer attaches to the side surface of the cover plate layer away from the touch layer and the side surface of the backplate layer away from the display layer. The one side surface of the first buffer layer attaches to the backplate layer, the display layer, the polarizer, the touch layer, and the cover plate layer. The one side surface of the first buffer layer flexibly connects to the backplate layer, the display layer, the polarizer, the touch layer, and the cover plate layer.

The cover plate layer and the backplate layer cover the display region and extend to the non-display region. The one side surface of the first buffer layer attaches to a side surface of the cover plate layer near the touch layer. The other side surface of the first buffer layer attaches to a side surface of the backplate layer near the display layer. The one side surface of the first buffer layer attaches to the display layer, the polarizer, and the touch layer. The one side surface of the first buffer layer flexibly connects to the backplate layer, the display layer, the polarizer, the touch layer, and the cover plate layer.

The cover plate layer covers the display region and extend to the non-display region. The backplate layer is located in the display region. The one side surface of the first buffer layer attaches to the side surface of the cover plate layer near the touch layer. The other side surface of the first buffer layer is coplanar with the side surface of the backplate layer away from the display layer. The one side surface of the first buffer layer attaches to the backplate layer, the display layer, the polarizer, and a side surface of the touch layer. The one side surface of the first buffer layer flexibly connects to the backplate layer, the display layer, the polarizer, the touch layer, and the cover plate layer.

The first buffer layer is selected from the group consisting of photoresist, rubber, an acrylate, polyurethane, and silicone.

Any neighboring two surfaces of film layers of the backplate layer, the display layer, the polarizer, the touch layer, and the cover plate layer are connected by a binding material.

The binding material is photoresist.

Different from the prior art, the present invention provides a display panel, and the display panel includes a display region and a non-display region located outside the display region. The display panel includes a first buffer layer and a plurality of display region film layers. The first buffer layer is located in the non-display region. The first buffer layer flexibly connects to at least two of the plurality of display region film layers. When displacement occurs in the display region film layers, the first buffer layer can generate a force opposite to the direction of the displacement of the display region film layers, resist the shear stress between the display region film layers, and prevent the display panel from peeling.

### DESCRIPTION OF THE DRAWINGS

In order to describe technical solutions in the present invention clearly, drawings to be used in the description of embodiments will be described briefly below. Apparently, drawings described below are only for some embodiments of the present invention, and other drawings may be obtained by those skilled in the art based on these drawings without creative efforts.

FIG. 1 is a plane structural diagram of a first embodiment of the display panel provided by the present invention.

FIG. 2 is a sectional structural diagram of the display panel in FIG. 1.

FIG. 3 is a sectional structural diagram of a second embodiment of the display panel provided by the present invention.

FIG. 4 is a sectional structural diagram of a third embodiment of the display panel provided by the present invention.

FIG. 5 is a sectional structural diagram of a fourth embodiment of the display panel provided by the present invention.

### DETAILED DESCRIPTION

In order to describe technical solutions in the present invention clearly, drawings to be used in the description of embodiments will be described briefly below. Apparently, drawings described below are only for some embodiments of the present invention, and other drawings may be obtained by those skilled in the art based on these drawings without creative efforts.

In the description of the present invention, it is to be understood that the terms “center,” “longitudinal,” “lateral,” “length,” “width,” “thickness,” “up,” “down,” “front,” “back,” “left,” “right,” “vertical,” “horizontal,” “top,” “bottom,” “inside,” “outside,” and the like, indicate orientations or positional relationships, and are based on the orientations or positional relationships shown in the drawings, merely for the purpose of facilitating the description of the present invention and the simplified description, rather than indicating or implying that the devices or elements have to have a specific orientation, or be constructed and operated in a particular orientation, and therefore may not be construed as limits to the present invention. In addition, the terms “first” and “second” are merely used for illustrative purposes only, but are not to be construed as indicating or imposing a relative importance or implicitly indicating the number of technical features indicated. Thus, a feature that defines “first” or “second” may expressly or implicitly comprise one or more of the features. In the description of the present invention, the meaning of “plural” is two or more, unless otherwise specified.

The word “exemplary” is used herein to mean “serving as an example, instance, or illustration.” Any embodiment or design described herein as “exemplary” is not necessarily to be construed as preferred or advantageous over other embodiments or designs. The following descriptions are presented to enable any person skilled in the art to make and use the invention. Descriptions of specific embodiments and applications are provided only as examples. Various modifications and combinations of the examples described herein will be readily apparent to those skilled in the art, and the general principles defined herein may be applied to other examples and applications without departing from the spirit and scope of the invention. Thus, the present invention is not intended to be limited to the examples described and shown, but is to be accorded the widest scope consistent with the principles and features disclosed herein.

The present invention provides a display panel, and the display panel includes a display region and a non-display region located outside the display region. The display panel includes a first buffer layer and a plurality of display region film layers. The first buffer layer is located in the non-display region. The first buffer layer flexibly connects to at least two of the plurality of display region film layers. The display panel of the embodiments of the present invention can be applied to various display devices. The details are described below.

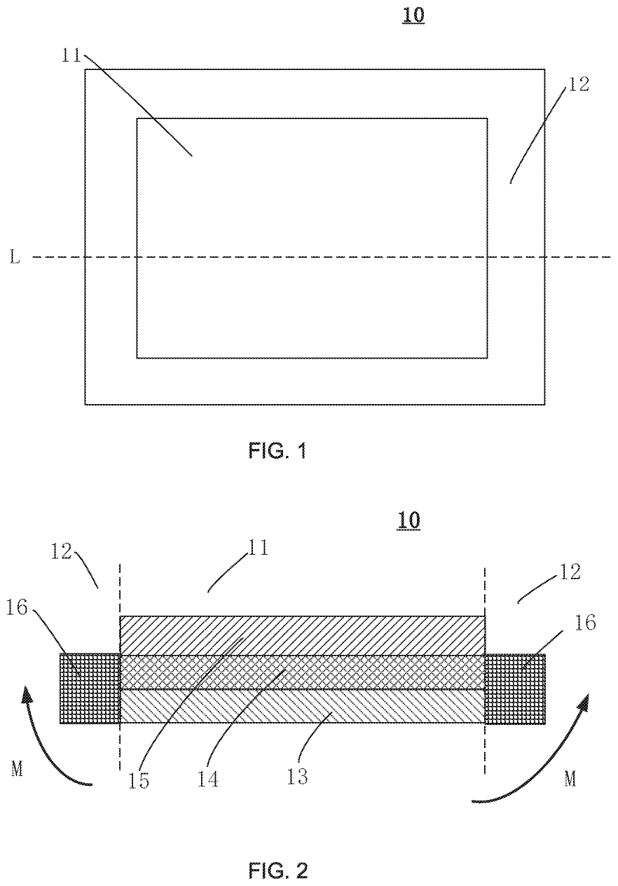

Please refer to FIG. 1, which is a plane structural diagram of a first embodiment of the display panel provided by the present invention. FIG. 2 is a sectional structural diagram of the display panel in FIG. 1, wherein FIG. 2 is a sectional structural diagram according to the section L of the display panel in FIG. 1.

In this embodiment, the display panel 10 includes a display region 11 and a non-display region 12 located outside the display region. The display panel 10 includes a first buffer layer 16 and three display region film layers. The three display region film layers are a first display region film layer 13, a second display region film layer 14, and a third display region film layer 15, respectively. The three display region film layers are laminated on the display region 11. The first buffer layer 16 is located in the non-display region 12, and the first buffer layer 16 flexibly connects to the first display region film layer 13 and the second display region film layer 14. The flexible connection can be an elastic connection, an elastic-plastic connection, a plastic connection, etc., which is not limited thereto in this invention. When the display panel 10 is bent in the M direction or in the opposite direction, a relative displacement occurs between the first display region film layer 13 and the second display region film layer 14, thereby generating interlayer shear stress. Because the first buffer layer 16 flexibly connects to the first display region film layer 13 and the second display region film layer 14, a reaction force opposite to the relative displacement direction is generated inside the first buffer layer 16. When the relative displacement is fixed, the reaction force inside the first buffer layer 16 resists a part of the force generated by the relative displacement of the film layer, thereby reducing the interlayer stress between the display region film layers, and avoiding the peeling of the film layer of the display panel 10. The first buffer layer 16 is deformed following the relative displacement of the display region film layers, and it prevents the film layer of the display panel 10 from peeling.

In a preferred embodiment, the flexible connection is an elastic connection. After the external force that causes the relative displacement of the display region film layers is released, the first buffer layer 16 restores the display region film layers to the original state in time, thereby preventing the display panel 10 from peeling after repeatedly bending.

In other embodiments, the first buffer layer 16 can flexibly connect the first display region film layer 13 and the second display region film layer 15, flexibly connect the second display region film layer 14 and the third display region film layer 15, or flexibly connect the first display region film layer 13, the second display region film layer 14, and the third display region film layer 15 which is not limited thereto in this invention.

In more embodiments, it is not limited thereto in this invention that the display panel 10 can include two, four, or more display region film layers, and the first buffer layer 16 flexibly connects to at least two of the plurality of display region film layers. For example, the display panel 10 includes five display region film layers, and the first buffer layer 16 is flexibly connects three display region film layers of five display region film layers.

Different from the prior art, the present invention provides a display panel, and the display panel includes a display region and a non-display region located outside the display region. The display panel includes a first buffer layer and a plurality of display region film layers. The first buffer layer is located in the non-display region. The first buffer layer flexibly connects to at least two of the plurality of display region film layers. A first buffer layer located in the display region flexibly connects to at least a portion of the display film layer. When displacement occurs in the display region film layers, the first buffer layer can generate a force opposite to the direction of the displacement of the display region film layers, resist the shear stress between the display region film layers, and prevent the display panel from peeling.

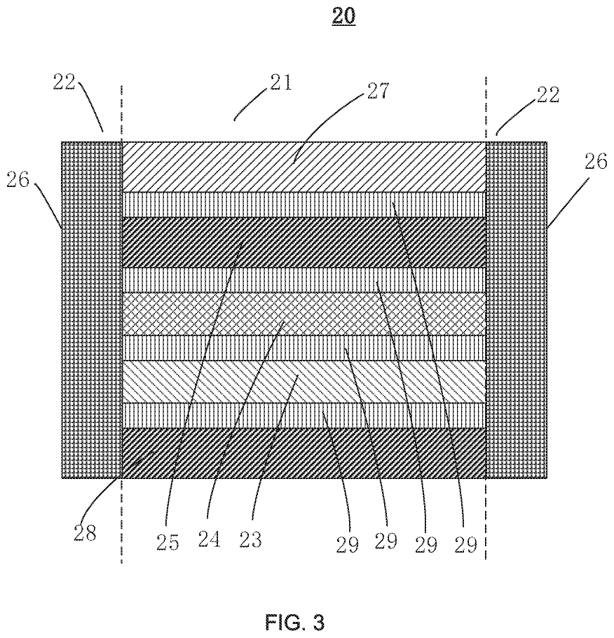

For a detailed description of the structure of the display panel of the present invention, please refer to FIG. 3, which is a sectional structural diagram of a second embodiment of the display panel provided by the present invention.

In this embodiment, a display panel 20 includes a display region 21, and a non-display region 22 located outside the display region 21.

In this embodiment, the display panel 20 includes a plurality of display region film layers and a first buffer layer 26. The plurality of display region film layers include a display layer 23, a polarizer 24, and a touch layer 25 disposed in sequence. The display layer 23, the polarizer 24, and the touch layer 25 are located in the display region 21. The first buffer layer 26 is located in the non-display region 22. A backplate layer 28 is disposed on a side of the display layer 23 away from the polarizer 24. A cover plate layer 27 is disposed on the side of the touch layer 25 away from the polarizer 24. The first buffer layer 26 flexibly connects to the backplate layer 28, the display layer 23, the polarizer 24, the touch layer 25, the cover plate layer 27. In other embodiment, it is not limited thereto in this invention that the display region film layers can be other film layers.

In this embodiment, the cover plate layer 27 and the backplate layer 28 are located in the display region 21. One side surface of the first buffer layer 26 is coplanar with a side surface of the cover plate layer 27 away from the touch layer 25, and the other side surface of the first buffer layer 26 is coplanar with a side surface of the backplate layer 28 away from the display layer 23. The one side surface of the first buffer layer 26 attaches to the backplate layer 28, the display layer 23, the polarizer 24, the touch layer 25, and the side surface of the cover plate layer 27. The one side surface of the first buffer layer 26 flexibly connects to the backplate layer 28, the display layer 23, the polarizer 24, the touch layer 25, and the cover plate layer 27. The backplate layer 28, the display layer 23, the polarizer 24, the touch layer 25, and the cover plate layer 27 are reinforced as one piece to prevent the film layers from peeling.

In this embodiment, the first buffer layer 26 is selected from the group consisting of photoresist, rubber, an acrylate, polyurethane, and silicone.

Further, any neighboring two surfaces of film layers of the backplate layer 28, the display layer 23, the polarizer 24, the touch layer 25, and the cover plate layer 27 are connected by a binding material 29. Preferably, the binding material 29 is a photoresist. In other embodiment, it is not limited thereto in this invention that the binding material 29 can be other material. The binding material 29 binds neighboring two surfaces of film layers, resists the shear stress between the display region film layers, prevents the film layers from peeling.

Different from the prior art, the present invention provides a display panel, and the display panel includes a display region and a non-display region located outside the display region. The display panel includes a first buffer layer and a plurality of display region film layers. The first buffer layer is located in the non-display region. The first buffer layer flexibly connects to at least two of the plurality of display region film layers. A first buffer layer located in the display region flexibly connects to at least a portion of the display film layer. When displacement occurs in the display region film layers, the first buffer layer can generate a force opposite to the direction of the displacement of the display region film layers, resist the shear stress between the display region film layers, and prevent the display panel from peeling.

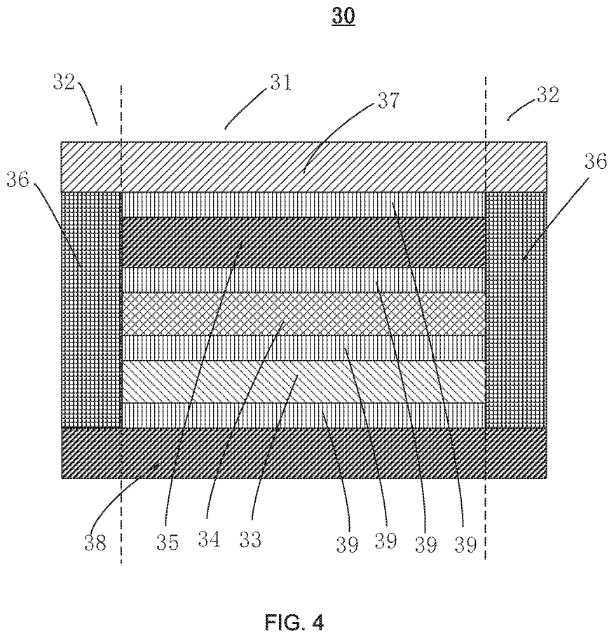

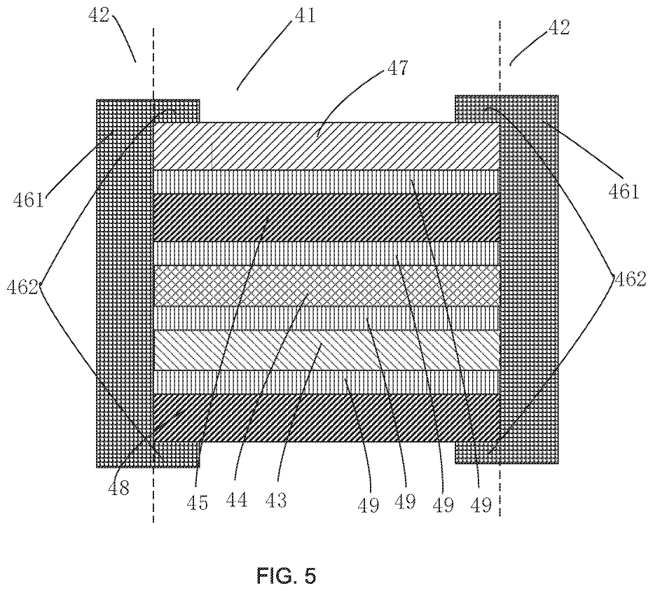

Further, refer to FIG. 4, which is a sectional structural diagram of a third embodiment of the display panel provided by the present invention.

In this embodiment, a display panel 30 includes a display region 31, and a non-display region 32 located outside the display region 31.

In this embodiment, the display panel 30 includes a plurality of display region film layers and a first buffer layer 36. The plurality of display region film layers include a display layer 33, a polarizer 34, and a touch layer 35 disposed in sequence. The display layer 33, the polarizer 34, and the touch layer 35 are located in the display region 31. The first buffer layer 36 is located in the non-display region 32. A backplate layer 38 is disposed on a side of the display layer 33 away from the polarizer 34. A cover plate layer 37 is disposed on the side of the touch layer 35 away from the polarizer 34. The first buffer layer 36 flexibly connects to the backplate layer 38, the display layer 33, the polarizer 34, the touch layer 35, the cover plate layer 37. In other embodiment, it is not limited thereto in this invention that the display region film layers can be other film layers.

In this embodiment, the cover plate layer 37 and the backplate layer 38 cover the display region 31 and extend to the non-display region 32. The one side surface of the first buffer layer 36 attaches to a side surface of the cover plate layer 37 near the touch layer 35. The other side surface of the first buffer layer 36 attaches to a side surface of the backplate layer 38 near the display layer 33. The one side surface of the first buffer layer 36 attaches to the display layer 33, the polarizer 34, and the touch layer 35. The one side surface of the first buffer layer 36 flexibly connects to the backplate layer 38, the display layer 33, the polarizer 34, the touch layer 35, and the cover plate layer 37. In this embodiment, the first buffer layer 36 can flexibly connects to the cover plate layer 37 and the backplate layer 38 when the cover plate layer 37 and the backplate layer 38 are different size.

In other embodiment, the cover plate layer 37 covers the display region 31 and extend to the non-display region 32. The backplate layer 38 is located in the display region 31. The one side surface of the first buffer layer 36 attaches to the side surface of the cover plate layer 37 near the touch layer 35. The other side surface of the first buffer layer 36 is coplanar with the side surface of the backplate layer 38 away from the display layer 33. The one side surface of the first buffer layer 36 attaches to the backplate layer 38, the display layer 33, the polarizer 34, and a side surface of the touch layer 35. The one side surface of the first buffer layer 36 flexibly connects to the backplate layer 38, the display layer 33, the polarizer 34, the touch layer 35, and the cover plate layer 37.

Further, refer to FIG. 4, which is a sectional structural diagram of a fourth embodiment of the display panel provided by the present invention.

In this embodiment, a display panel 40 includes a display region 41, and a non-display region 42 located outside the display region 41.

In this embodiment, the display panel 40 includes a plurality of display region film layers and a first buffer layer 461. The plurality of display region film layers include a display layer 43, a polarizer 44, and a touch layer 45 disposed in sequence. The display layer 43, the polarizer 44, and the touch layer 45 are located in the display region 41. The first buffer layer 461 is located in the non-display region 42. A backplate layer 48 is disposed on a side of the display layer 43 away from the polarizer 44. A cover plate layer 47 is disposed on the side of the touch layer 45 away from the polarizer 44. The first buffer layer 461 flexibly connects to the backplate layer 48, the display layer 43, the polarizer 44, the touch layer 45, the cover plate layer 47. In other embodiment, it is not limited thereto in this invention that the display region film layers can be other film layers.

In this embodiment, the display panel 40 further includes a second buffer layer 462 located in the display region 41. The cover plate layer 47 and the backplate layer 48 are located in the display region 41. The second buffer layer 462 is integrally formed with the first buffer layer 461. The second buffer layer 462 attaches to the side surface of the cover plate layer 47 away from the touch layer 45 and the side surface of the backplate layer 48 away from the display layer 43. The one side surface of the first buffer layer 461 attaches to the backplate layer 48, the display layer 43, the polarizer 44, the touch layer 45, and the cover plate layer 47. The one side surface of the first buffer layer 461 flexibly connects to the backplate layer 48, the display layer 43, the polarizer 44, the touch layer 45, and the cover plate layer 47. The second buffer layer 462 is located in the display region 41, and the second buffer layer 462 attaches to the side surface of the cover plate layer 47 away from the touch layer 45. It increases the contact area of the second buffer layer 462, the first buffer layer 461, and the cover plate layer 47. It prevents stress concentrating on a surface of the cover plate layer 47, and will not let the cover plate layer 47 damage. Similarly, it prevents stress concentrating on a surface of the backplate layer 48, and will not let the backplate layer 48 damage.

Preferably, the second buffer layer 462 is a transparent material. It prevents the second buffer layer 462 affecting the display effect of the display region 41.

The embodiments described above are only describe the structure above. It is not limited herein that the display panel in the embodiments of the present invention can include any other necessary structure.

In an actual implementation, each unit or structure can be implemented as a separate entity, or can be combined in any combination as one or several entities. Specific embodiments of each unit or structure can be implemented referring to the previous method.

The display panel provided by embodiments of the present disclosure is described in detail above, the specific examples of this document are used to explain principles and embodiments of the present disclosure, and the description of embodiments above is only for helping to understand the present disclosure. Meanwhile, those skilled in the art will be able to change the specific embodiments and the scope of the disclosure according to the idea of the present disclosure. In the above, the content of the specification should not be construed as limiting the present disclosure. Above all, the content of the specification should not be the limitation of the present disclosure.

What is claimed is:

1. A display panel, comprising:
a display region;
a non-display region located outside the display region;
a first buffer layer; and
a plurality of display region film layers, the first buffer layer located in the non-display region, and the first buffer layer flexibly connects to at least two of the plurality of display region film layers;
wherein the plurality of display region film layers comprise a display layer, a polarizer, and a touch layer disposed in sequence, a backplate layer is disposed on a side of the display layer away from the polarizer, a cover plate layer is disposed on the side of the touch layer away from the polarizer, and the first buffer layer flexibly connects to the backplate layer, the display layer, the polarizer, the touch layer, the cover plate layer; and
wherein the first buffer layer is selected from the group consisting of photoresist, rubber, an acrylate, polyurethane, and silicone.

2. The display panel as claimed in claim 1, wherein the cover plate layer and the backplate layer are located in the display region;
wherein one side surface of the first buffer layer is coplanar with a side surface of the cover plate layer away from the touch layer, and the other side surface of the first buffer layer is coplanar with a side surface of the backplate layer away from the display layer;
wherein the one side surface of the first buffer layer attaches to the backplate layer, the display layer, the polarizer, the touch layer, and the side surface of the cover plate layer; and
wherein the one side surface of the first buffer layer flexibly connects to the backplate layer, the display layer, the polarizer, the touch layer, and the cover plate layer.

3. A display panel, comprising:
a display region;
a non-display region located outside the display region;
a first buffer layer; and
a plurality of display region film layers, the first buffer layer located in the non-display region, and the first buffer layer flexibly connects to at least two of the plurality of display region film layers.

4. The display panel as claimed in claim 3, wherein the plurality of display region film layers comprise a display layer, a polarizer, and a touch layer disposed in sequence, a backplate layer is disposed on a side of the display layer away from the polarizer, a cover plate layer is disposed on the side of the touch layer away from the polarizer, and the first buffer layer flexibly connects to the backplate layer, the display layer, the polarizer, the touch layer, the cover plate layer.

5. The display panel as claimed in claim 4, wherein the cover plate layer and the backplate layer are located in the display region;
wherein one side surface of the first buffer layer is coplanar with a side surface of the cover plate layer away from the touch layer, and the other side surface of the first buffer layer is coplanar with a side surface of the backplate layer away from the display layer;
wherein the one side surface of the first buffer layer attaches to the backplate layer, the display layer, the polarizer, the touch layer, and the side surface of the cover plate layer; and
wherein the one side surface of the first buffer layer flexibly connects to the backplate layer, the display layer, the polarizer, the touch layer, and the cover plate layer.

6. The display panel as claimed in claim 4, wherein the display panel further comprises a second buffer layer located in the display region;
wherein the cover plate layer and the backplate layer are located in the display region;
wherein the second buffer layer is integrally formed with the first buffer layer;
wherein the second buffer layer attaches to the side surface of the cover plate layer away from the touch layer and the side surface of the backplate layer away from the display layer;
wherein the one side surface of the first buffer layer attaches to the backplate layer, the display layer, the polarizer, the touch layer, and the cover plate layer; and
wherein the one side surface of the first buffer layer flexibly connects to the backplate layer, the display layer, the polarizer, the touch layer, and the cover plate layer.

7. The display panel as claimed in claim 4, wherein the cover plate layer and the backplate layer cover the display region and extend to the non-display region;
wherein the one side surface of the first buffer layer attaches to a side surface of the cover plate layer near the touch layer, and the other side surface of the first buffer layer attaches to a side surface of the backplate layer near the display layer;
wherein the one side surface of the first buffer layer attaches to the display layer, the polarizer, and the touch layer; and
wherein the one side surface of the first buffer layer flexibly connects to the backplate layer, the display layer, the polarizer, the touch layer, and the cover plate layer.

8. The display panel as claimed in claim 4, wherein the cover plate layer covers the display region and extend to the non-display region;
wherein the backplate layer is located in the display region;
wherein the one side surface of the first buffer layer attaches to the side surface of the cover plate layer near the touch layer, and the other side surface of the first buffer layer is coplanar with the side surface of the backplate layer away from the display layer;
wherein the one side surface of the first buffer layer attaches to the backplate layer, the display layer, the polarizer, and a side surface of the touch layer; and
wherein the one side surface of the first buffer layer flexibly connects to the backplate layer, the display layer, the polarizer, the touch layer, and the cover plate layer.

9. The display panel as claimed in claim 3, wherein the first buffer layer is selected from the group consisting of photoresist, rubber, an acrylate, polyurethane, and silicone.

10. The display panel as claimed in claim 4, wherein any neighboring two surfaces of film layers of the backplate layer, the display layer, the polarizer, the touch layer, and the cover plate layer are connected by a binding material.

11. The display panel as claimed in claim 10, wherein the binding material is photoresist.

12. A display device, wherein the display device comprises a display panel, the display panel comprises a display region, a non-display region located outside the display region, a first buffer layer, and a plurality of display region film layers; and
wherein the first buffer layer is located in the non-display region, and the first buffer layer flexibly connects to at least two of the plurality of display region film layers.

13. The display device as claimed in claim 12, wherein the plurality of display region film layers comprise a display layer, a polarizer, and a touch layer disposed in sequence, a backplate layer is disposed on a side of the display layer away from the polarizer, a cover plate layer is disposed on the side of the touch layer away from the polarizer, and wherein the first buffer layer flexibly connects to the backplate layer, the display layer, the polarizer, the touch layer, the cover plate layer.

14. The display device as claimed in claim 13, wherein the cover plate layer and the backplate layer are located in the display region;
wherein one side surface of the first buffer layer is coplanar with a side surface of the cover plate layer away from the touch layer, and the other side surface of the first buffer layer is coplanar with a side surface of the backplate layer away from the display layer;
wherein the one side surface of the first buffer layer attaches to the backplate layer, the display layer, the polarizer, the touch layer, and the side surface of the cover plate layer; and
wherein the one side surface of the first buffer layer flexibly connects to the backplate layer, the display layer, the polarizer, the touch layer, and the cover plate layer.

15. The display device as claimed in claim 13, wherein the display panel further comprises a second buffer layer located in the display region;
wherein the cover plate layer and the backplate layer are located in the display region;
wherein the second buffer layer is integrally formed with the first buffer layer;
wherein the second buffer layer attaches to the side surface of the cover plate layer away from the touch layer and the side surface of the backplate layer away from the display layer;
wherein the one side surface of the first buffer layer attaches to the backplate layer, the display layer, the polarizer, the touch layer, and the cover plate layer; and
wherein the one side surface of the first buffer layer flexibly connects to the backplate layer, the display layer, the polarizer, the touch layer, and the cover plate layer.

16. The display device as claimed in claim 13, wherein the cover plate layer and the backplate layer cover the display region and extend to the non-display region;
wherein the one side surface of the first buffer layer attaches to a side surface of the cover plate layer near the touch layer, and the other side surface of the first buffer layer attaches to a side surface of the backplate layer near the display layer;
wherein the one side surface of the first buffer layer attaches to the display layer, the polarizer, and the touch layer; and
wherein the one side surface of the first buffer layer flexibly connects to the backplate layer, the display layer, the polarizer, the touch layer, and the cover plate layer.

17. The display device as claimed in claim 13, wherein the cover plate layer covers the display region and extend to the non-display region;
wherein the backplate layer is located in the display region;
wherein the one side surface of the first buffer layer attaches to the side surface of the cover plate layer near the touch layer, and the other side surface of the first buffer layer is coplanar with the side surface of the backplate layer away from the display layer;
wherein the one side surface of the first buffer layer attaches to the backplate layer, the display layer, the polarizer, and a side surface of the touch layer; and
wherein the one side surface of the first buffer layer flexibly connects to the backplate layer, the display layer, the polarizer, the touch layer, and the cover plate layer.

18. The display device as claimed in claim 12, wherein the first buffer layer is selected from the group consisting of photoresist, rubber, an acrylate, polyurethane, and silicone.

19. The display device as claimed in claim 13, wherein any neighboring two surfaces of film layers of the backplate layer, the display layer, the polarizer, the touch layer, and the cover plate layer are connected by a binding material.

20. The display device as claimed in claim 19, wherein the binding material is photoresist.
